(19) United States
(12) Patent Application Publication
(10) Pub. No.: US 2015/0168992 A1
(43) Pub. Date: Jun. 18, 2015

(54) CONFIGURABLE CLOCK MESH CIRCUIT AND DEVICES INCLUDING THE SAME

(71) Applicant: Samsung Electronics Co., Ltd., Suwon-si (KR)

(72) Inventor: Jong-Sang CHOI, Seoul (KR)

(21) Appl. No.: 14/554,895

(22) Filed: Nov. 26, 2014

(30) Foreign Application Priority Data
Dec. 13, 2013 (KR) 10-2013-0155210

(51) Int. Cl. G06F 1/12; H03K 19/0175; H03K 17/693; G06F 1/10; H03K 17/00

(52) U.S. Cl. CPC G06F 1/12; G06F 1/10; H03K 17/005; H03K 17/693; H03K 19/017509

(57) ABSTRACT

A clock mesh circuit includes a first clock circuit, a second clock circuit, and a switch circuit. The first clock circuit includes a first clock mesh network, and is configured to transmit a received clock signal to a first load circuit. The second clock circuit includes a second clock mesh network separate from the first clock mesh network, and is configured to transmit the clock signal to a second load circuit. The switch circuit connects the first clock circuit to the second clock circuit. The switch circuit connects the first clock mesh network to the second clock mesh network. The clock mesh circuit is configured such that the clock signal is transmitted to the first and second load circuits when the switch circuit is turned-on, and the clock signal is transmitted to either the first load circuit or the second load circuit when the switch circuit is turned-off.

### CROSS-REFERENCE TO RELATED APPLICATIONS

This application claims priority under 35 U.S.C. §119(a) to Korean Patent Application No. 10-2013-0155210 filed on Dec. 13, 2013, the disclosure of which is hereby incorporated by reference in its entirety.

### BACKGROUND

Embodiments of the present inventive concept relate to a clock mesh circuit, and more particularly to a configurable clock mesh circuit which may reduce a variation in a delay of a clock in multiple clock domains and devices including the same.

Various types of mobile devices have been developed in recent years, and the mobile devices typically include an integrated circuit (IC) for miniaturization and lightening of weight.

In general, mobile devices include various synchronization circuits which operate by being synchronized with a clock (or a clock signal). Recently, in order to reduce the variation in a delay of a clock, a clock mesh network has been widely used. However, the variation in a delay of a clock may frequently occur in a multiple clock mesh network, as opposed to a single clock mesh network. Therefore, it may be desired to reduce the variation in a delay of clock signals in a multiple clock mesh network.

### SUMMARY

Exemplary embodiments of the disclosure describe a configurable clock mesh circuit which has a structure of synchronizing a clock with other clocks between clock domains so as to reduce a change in a delay of the clock between multiple clock domains, an operation method thereof, and devices including the same.

An exemplary embodiment of the present inventive concepts is directed to a clock mesh circuit. The clock mesh circuit includes a first clock circuit, a second clock circuit, and a switch circuit. The first clock circuit includes a first clock mesh network, and is configured to transmit a received clock signal to a first load circuit. The second clock circuit includes a second clock mesh network separate from the first clock mesh network, and is configured to transmit the clock signal to a second load circuit. The switch circuit connects the first clock mesh network to the second clock mesh network.

The switch circuit may connect the first clock mesh network and the second clock mesh network in response to a switch signal.

When the first clock circuit further includes a first clock mesh driver, and the second clock circuit further includes a second mesh driver, the switch circuit may connect the first clock mesh driver to the second clock mesh driver in response to a switch signal.

The first clock circuit may further include a plurality of local clock gating circuits which transmit or block a clock signal output from the first clock mesh network to or from a corresponding load circuit of the load circuits in response to a respective enable signal, and a local switch circuit configured to connect output terminals of the plurality of local clock gating circuits to each other in response to a local switch signal.

An exemplary embodiment of the present inventive concepts is directed to a system on chip or an application processor, including the clock mesh circuit and a clock source which generates a clock supplied to the clock mesh circuit.

The clock mesh circuit may be dispersed to be located in different parts of the system-on chip.

An exemplary embodiment of the present inventive concepts is directed to a portable electronic device, including a display, an external memory, and a system on chip which includes the clock mesh circuit and a clock source generating a clock supplied to the clock mesh circuit. The system on chip further includes a display controller which controls an operation of the display, and a memory controller which controls an operation of the external memory.

An exemplary embodiment of the present inventive concepts is directed to a method of providing a clock signal to one or more load circuits using a clock mesh circuit. The clock mesh circuit includes a first clock circuit, a second clock circuit, and a switch circuit. The first clock circuit includes a first clock mesh network configured to receive an input clock signal and to output a first output clock signal to a first load circuit. The second clock circuit includes a second clock mesh network configured to receive the input clock signal and to output a second output clock signal to a second load circuit. The switch circuit is configured to electrically connect and electrically disconnect the first clock circuit to and from the second clock circuit. The method includes receiving the input clock signal at one or more of the first and second clock circuits; outputting a respective output clock signal to respective one or more load circuits based on the received input clock signal; when the input clock signal is input to both the first clock circuit and the second clock circuit, electrically connecting the first clock circuit to the second clock circuit using the switch circuit; and when the input clock signal is input to either the first clock circuit or the second clock circuit but not both, electrically disconnecting the first clock circuit from the second clock circuit using the switch circuit.

An exemplary embodiment of the present inventive concepts is directed to a semiconductor device. The semiconductor device includes a first clock circuit, a second clock circuit, and a switch circuit. The first clock circuit includes a first clock distribution circuit including a first clock tree circuit and a first mesh wiring that contacts output terminals of the first clock tree circuit, and a first clock gating circuit configured to transmit a clock signal to the first clock tree circuit in response to a first enable signal. The second clock circuit includes a second clock distribution circuit including a second clock tree circuit and a second mesh wiring that contacts output terminals of the second clock tree circuit, and a second clock gating circuit configured to transmit the clock signal to the second clock tree circuit in response to a second enable signal. The switch circuit is configured to electrically connect and disconnect the first clock distribution circuit to/from the second clock distribution circuit in response to a switch signal.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram which represents an exemplary embodiment of a system on chip (SoC) including a clock mesh circuit according to an exemplary embodiment of the present inventive concepts;

FIG. 2 is a block diagram which represents another exemplary embodiment of the SoC including a clock mesh circuit illustrated in FIG. 1;

FIG. 3 is a block diagram which represents still another exemplary embodiment of the SoC including a clock mesh circuit illustrated in FIG. 1;

FIG. 4 is a block diagram which represents still another exemplary embodiment of the SoC including a clock mesh circuit illustrated in FIG. 1;

FIG. 5 is a block diagram which represents still another exemplary embodiment of the SoC including a clock mesh circuit having a local clock gating circuit;

FIG. 6 is a circuit diagram which represents an exemplary embodiment of a switch circuit illustrated in FIG. 3 and FIG. 4;

FIG. 7 is a circuit diagram which represents another exemplary embodiment of the switch circuit illustrated in FIG. 3 and FIG. 4;

FIG. 8 is a circuit diagram which represents still another exemplary embodiment of the switch circuit illustrated in FIG. 3 and FIG. 4;

FIG. 9 is a flowchart which represents a method of operating the system on chip including a clock mesh circuit according to an exemplary embodiment of the present inventive concepts; and

FIG. 10 is a flowchart which represents a method of providing a clock signal to one or more load circuits using a clock mesh circuit according to an exemplary embodiment of the present inventive concepts.

### DETAILED DESCRIPTION OF THE EMBODIMENTS

The present disclosure now will be described more fully hereinafter with reference to the accompanying drawings, in which embodiments of the invention are shown. This invention may, however, be embodied in many different forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”. The term “contact,” as used herein, refers to a direct contact, unless indicated otherwise.

It will be understood that, although the terms first, second, etc. may be used herein to describe various elements, these elements should not be limited by these terms. Unless indicated otherwise, these terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Expressions such as “at least one of,” when preceding a list of elements, modify the entire list of elements and do not modify the individual elements of the list. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless the context indicates otherwise, terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

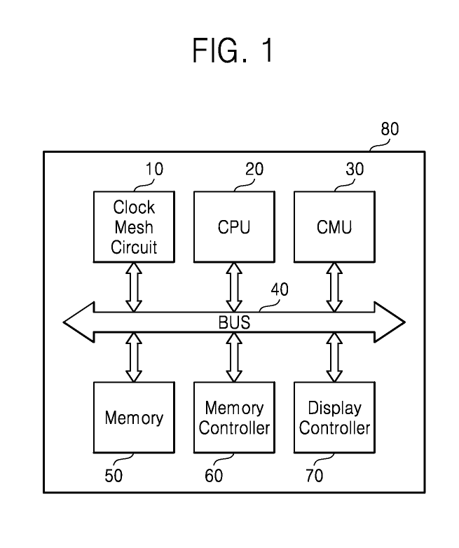

FIG. 1 is a block diagram which represents an exemplary embodiment of a system on chip (SoC) including a clock mesh circuit according to an exemplary embodiment of the present inventive concepts. Referring to FIG. 1, an SoC 80 includes a clock mesh circuit 10, a central processing unit (CPU) 20, a clock management unit (CMU) 30, a memory (e.g., memory chip) 50, a memory controller 60, and a display controller 70. In addition, the SoC 80 may additionally include a graphics processing unit (GPU) (not shown). The SoC 80 may be, for example, a piece of a semiconductor wafer.

The SoC 80 may be included in, for example, a personal computer (PC) or a portable electronic device. The portable electronic device may be included in, for example, a smart phone, a tablet PC, a mobile internet device (MID), an internet tablet, a personal digital assistant (PDA), a wearable computer, or an electronic toy. In addition, the SoC 80 may be included in, for example, an application processor (AP) or a mobile AP. In example embodiments, the SoC 80 may be embodied in a part of the AP.

The clock mesh circuit 10 may supply a clock (or a clock signal) to each element CPU 20, memory 50, memory controller 60, and/or display controller 70 of the SoC 80. For convenience of description in FIG. 1, the clock mesh circuit 10 is illustrated as one additional circuit, but the clock mesh circuit 10 may be dispersed to be located in different parts of the SoC 80.

The CPU 20 may control each element CPU 20, memory 50, memory controller 60, and/or display controller 70 through a bus 40. The CPU 20 may process a program and/or data stored in the memory 50. The CMU 30 may control transmission of a clock generated by, for example, a phase locked loop (PLL) circuit or a delay locked loop (DLL) circuit.

According to exemplary embodiments, the CMU 30 may include the PLL circuit or the DLL circuit, and the CMU 30 may supply a clock generated by the PLL circuit or the DLL circuit embodied outside the CMU 30 to a corresponding element 10, 20, 50, 60, and/or 70. Accordingly, the PLL circuit, the DLL circuit, or the CMU 30 may perform a function of a clock source. For example, the CPU 20 or the CMU 30 may perform a function of controlling an operation of the clock mesh circuit 10.

The memory 50 may store a program and/or data necessary for an operation of the SoC 80. For example, the memory 50 may be embodied in an on-chip memory. The memory 50 may include, for example, a read only memory (ROM), an electrically erasable programmable read-only memory (EEPROM), a flash memory, a magnetic random access memory (MRAM), a spin-transfer torque MRAM, a conductive bridging RAM (CBRAM), a ferroelectric RAM (FeRAM), a phase change RAM (PRAM) which is also called an ovonic unified memory (OUM), a resistive RAM (RRAM or ReRAM), a nanotube RRAM, a polymer RAM (PoRAM), a nano floating gate memory (NFGM), a holographic memory, a molecular electronics memory device or an insulator resistance change memory, a dynamic random access memory (DRAM), a static RAM (SRAM), and/or a collective memory which includes another type of memory different from the above-mentioned memories.

The memory controller 60 may control an operation of an external memory embodied outside the SoC 80. The external memory controlled by the memory controller 60 may be a volatile memory like a DRAM or a non-volatile memory like a flash memory.

The display controller 70 may control an operation of a display embodied outside the SoC 80. The display may be embodied in, for example, a TFT-LCD, a LED display, an OLED display, an AMOLED display, or a flexible display.

The above-mentioned portable electronic device may include the SoC 80, an external memory controlled by the memory controller 60 and embodied outside the SoC 80, and a display controlled by the display controller 70 and embodied outside the SoC 80.

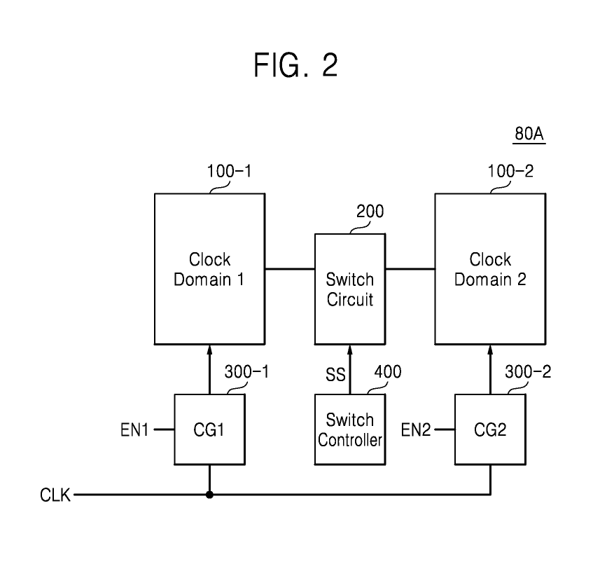

FIG. 2 is a block diagram which represents another exemplary embodiment of the SoC including a clock mesh circuit illustrated in FIG. 1. Referring to FIGS. 1 and 2, an SoC 80A may include a first clock domain (e.g., circuit) 100-1, a second clock domain (e.g., circuit) 100-2, a switch circuit 200, a first clock gating circuit 300-1, a second clock gating circuit 300-2, and a switch controller 400.

For convenience of description in FIG. 2, the SoC 80A including two clock domains 100-1 and 100-2 and peripheral circuits 200, 300-1, 300-2, and 400 is illustrated, but a technical concept of the inventive concepts is not limited thereto. Therefore, the SoC according to an exemplary embodiment of the present inventive concepts may include three or more clock domains and peripheral circuits capable of controlling an operation of the three or more clock domains. For example, all or a part of one or more elements 20, 50, 60, and 70 may be included in a corresponding clock domain 100-1 and 100-2.

The first clock domain 100-1 may receive a clock CLK output from the CMU 30 through the first clock gating circuit 300-1. A second clock domain 100-2 may receive a clock CLK through the second clock gating circuit 300-2.

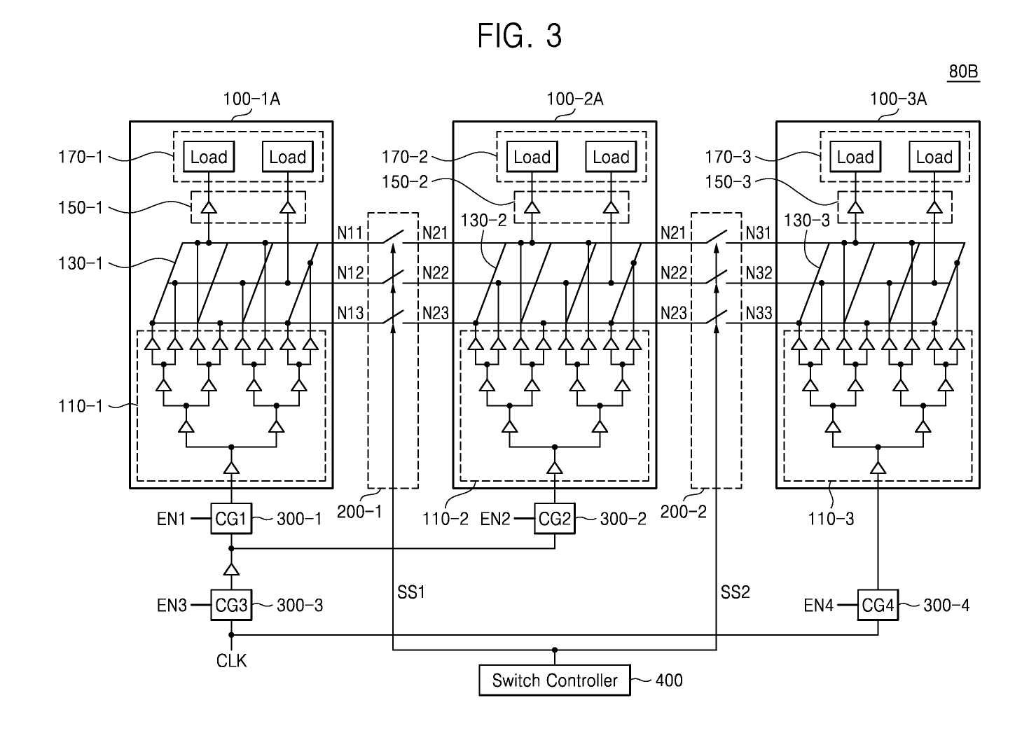

The switch circuit 200 may be located between the first clock domain 100-1 and the second clock domain 100-2, and connect the first clock domain 100-1 and the second clock domain 100-2 in response to a switch signal SS output from the switch controller 400. An example operation for the switch circuit 200 will be described in detail through FIGS. 3 to 8.

The first clock gating circuit 300-1 may control transmission of a clock CLK to the first clock domain 100-1 in response to a first enable signal EN1 output from a control circuit (not shown) of the CPU 20 or a control circuit (not shown) of the CMU 30.

The second clock gating circuit 300-2 may control transmission of a clock CLK to the second clock domain 100-2 in response to a second enable signal EN2 output from a control circuit of the CPU 20 or a control circuit of the CMU 30.

According to an exemplary embodiment, the first clock gating circuit 300-1 and the second clock gating circuit 300-2 may be embodied in a clock gating circuit transmitting a clock pulse. According to exemplary embodiments, the switch controller 400 may be embodied in the CMU 30.

FIG. 3 is a block diagram which represents still another exemplary embodiment of the SoC including a clock mesh circuit illustrated in FIG. 1. Referring to FIGS. 1 and 3, an SoC 80B may include a first clock domain (e.g., circuit) 100-1A, a second clock domain (e.g., circuit) 100-2A, a third clock domain (e.g., circuit) 100-3A, a first switch circuit 200-1, a second switch circuit 200-2, a first clock gating circuit 300-1, a second clock gating circuit 300-2, a third clock gating circuit 300-3, a fourth clock gating circuit 300-4, and a switch controller 400.

The first clock domain 100-1A includes a first clock mesh driver block (e.g., clock tree circuit) 110-1, a first clock mesh network (e.g., mesh wiring) 130-1, a first local clock gating block 150-1, and a first load block 170-1. A structure and an operation of each clock domain 100-2A and 100-3A are substantially the same as a structure and an operation of the clock domain 100-1A.

Each clock gating circuit 300-1, 300-2, 300-3, and 300-4 may control transmission of a clock CLK in response to each enable signal EN1, EN2, EN3, and EN4. According to exemplary embodiments, each enable signal EN1, EN2, EN3, and EN4 may be output from the CPU 20 or the CMU 30. For example, the first clock domain 100-1A is activated when the enable signals EN1 and EN3 are activated, the second clock domain 100-2A is activated when the enable signals EN2 and EN3 are activated, and the third clock domain 100-3A is activated when the enable signal EN4 is activated. Accordingly, the SoC may also reduce the power consumption by selectively operating at least one of the clock domains 100-1A, 100-2A, and 100-3A.

The first clock mesh driver block 110-1 may receive a clock CLK input through the first clock gating circuit 300-1, and include a plurality of hierarchy structure buffers (or drivers) for driving the first clock mesh network 130-1 using the clock signal CLK. For example, each of the clock mesh networks 130-1, 130-2, and 130-3 may be embodied in a mesh structure. Output terminals of the first clock mesh driver block 110-1 are connected to the first clock mesh network 130-1. Hereinafter, the first clock mesh driver block 110-1 and the first clock mesh network 130-1 may be referred to as a first clock distribution circuit.

In example embodiments, the mesh structure of each of the clock mesh networks 130-1, 130-2, and 130-3 may include a plurality of horizontal wirings and a plurality of vertical wirings connected to each other. For example, the horizontal wirings may be disposed in parallel with one another at predetermined intervals and the vertical wirings may be disposed in parallel with one another at predetermined intervals.

The first local clock gating block 150-1 may include a plurality of drivers (or buffers) which may receive a clock CLK through the clock mesh network 130-1 and transmit the clock CLK to a plurality of loads included in the first load block 170-1. The first local clock gating block 150-1 may perform gating or buffering on the clock CLK.

In one embodiment, the first load block 170-1 may include all or a part of one or more elements 20, 50, 60, and/or 70. In another embodiment, the first load block 170-1 may include a plurality of load circuits. For example, the plurality of load circuits may include a plurality of synchronization circuits, e.g., flip-flops. For example, the flip-flops may latch corresponding data in response to the clock CLK.

In example embodiments, the first switch circuit 200-1 may connect each node N11, N12, and N13 of a first clock domain 100-1A to each node N21, N22, and N23 of a second clock domain 100-2A in response to a first switch signal SS1 output from the switch controller 400. A clock signal received at the first load block 170-1 of the first clock domain 100-1A and a clock signal received at a second load block 170-2 of the second clock domain 100-2A may be synchronized with each other when the first switch circuit 200-1 is turned-on.

In example embodiments, the clock CLK is transmitted to the first and second load blocks 170-1 and 170-2 when the first switch circuit 200-1 is turned-on, and the clock CLK is transmitted to either the first load block 170-1 or the second load block 170-2 when the first switch circuit 200-1 is turned-off. For example, when the first switch circuit 200-1 is turned-on the enable signals EN1 to EN3 may be activated, and when the first switch circuit 200-1 is turned-off either the enable signal EN1 and EN3 may be activated or the enable signals EN2 and EN3 may be activated.

In example embodiments, the second switch circuit 200-2 may connect each node N21, N22, and N23 of the second clock domain 100-2A with each node N31, N32, and N33 of the third clock domain 100-3A in response to a second switch signal SS2 output from the switch controller 400. Through an operation of switching the second switch circuit 200-2 on, a clock signal received at the second load block 170-2 of the second clock domain 100-2A and a clock signal received at a third load block 170-3 of the third clock domain 100-3A may be synchronized with each other. The number of nodes connected by each switch circuit 200-1 and 200-2 may be variously changed according to exemplary embodiments.

Each clock gating circuits 300-1, 300-2, 300-3, and 300-4 may transmit or block a clock CLK to or from each corresponding clock domain 100-1A, 100-2A, and 100-3A in response to each corresponding enable signal EN1, EN2, EN3, and EN4.

The switch controller 400 may generate the switch signals SS1 and SS2 corresponding to a state (or operation) mode. Signals or information related to the state mode may be stored in a register (not shown) embedded in the switch controller 400.

Referring to FIG. 3 and Table 1, a state mode may be divided into four types according to exemplary embodiments, and the switch controller 400 may control activation timing and inactivation timing of each switch signal SS1 and SS2 according to the state mode. For example, “activated” may mean one of a first transition from a low level to a high level and a second transition from the high level to the low level, and “inactivated” may mean the other one of the first transition and the second transition. According to exemplary embodiments, the state mode may be determined by a plurality of enable signals EN1, EN2, EN3, and EN4.

TABLE 1

| | First clock | Second clock | Third clock | Switch signals |
|---|---|---|---|---|
| State mode | domain | domain | domain | (SS) |
| MODE1 | activated | inactivated | inactivated | SS1: 0, SS2: 0 |
| MODE2 | activated | activated | inactivated | SS1: 1, SS2: 0 |
| MODE3 | activated | activated | activated | SS1: 1, SS2: 1 |
| MODE4 | inactivated | activated | activated | SS1: 0, SS2: 1 |

For example, when the first clock domain 100-1A is activated, the second clock domain 100-2A is inactivated, and the third clock domain 100-3A is inactivated, the state mode is, for example, “MODEL”, and the switch controller 400 may generate a first switch signal SS1 having a low level and a second switch signal SS2 having a low level. At this time, the low level is indicated by “0”, and the high level is indicated by “1”. Moreover, it is assumed that “0” means a switch OFF and “1” means a switch ON in terms of switch operation.

When the first clock domain 100-1A is activated, the second clock domain 100-2A is activated, and the third clock domain 100-3A is inactivated, the state mode is, for example, “MODE2”, and the switch controller 400 may generate “1” for the first switch signal SS1 and “0” for the second switch signal SS2.

When the first clock domain 100-1A is activated, the second clock domain 100-2A is activated, and the third clock domain 100-3A is activated, the state mode is, for example, “MODE3”, and the switch controller 400 may generate “1” for the first switch signal SS1 and “1” for the second switch signals SS2.

When the first clock domain 100-1a is inactivated, the second clock domain 100-2A is activated, and the third clock domain 100-3A is activated, the state mode is, for example, “MODE4”, and the switch controller 400 may generate “0” for the first switch signal SS1 and “1” for the second switch signal SS2. Table 1 is not more than an exemplary embodiment for convenience of description.

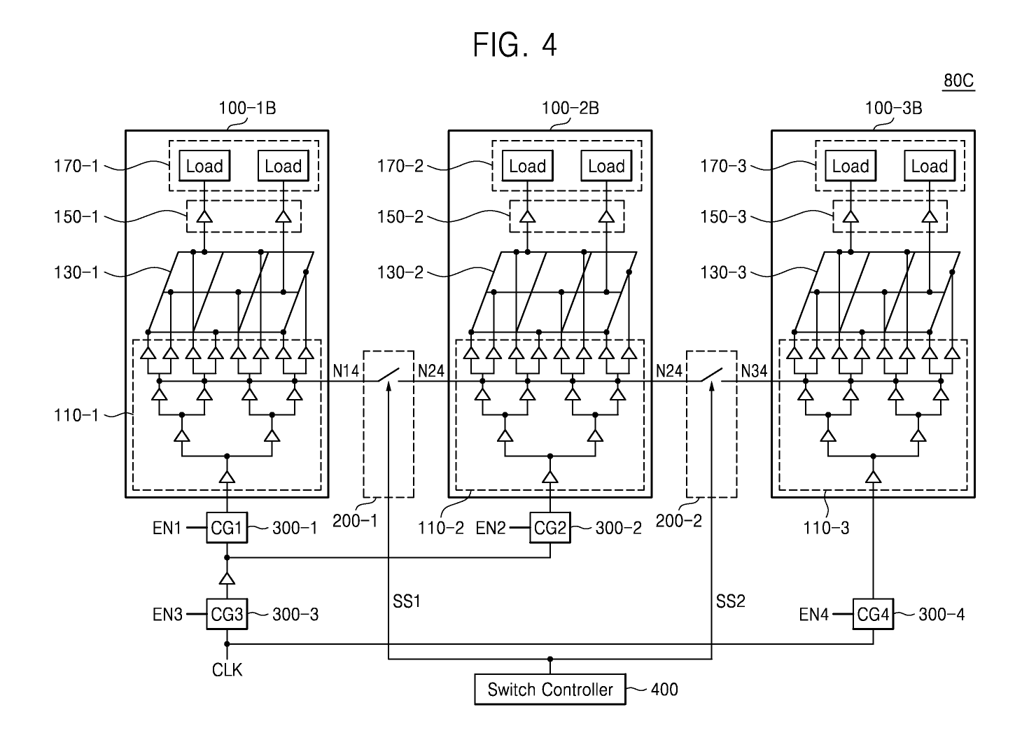

FIG. 4 is a block diagram which represents still another exemplary embodiment of the SoC including a clock mesh circuit illustrated in FIG. 1.

Referring to FIGS. 1 and 4, an SoC 80C includes a first clock domain 100-1B, a second clock domain 100-2B, a third clock domain 100-3B, a first switch circuit 200-1, a second switch circuit 200-2, a first clock gating circuit 300-1, a second clock gating circuit 300-2, a third clock gating circuit 300-3, a fourth clock gating circuit 300-4, and a switch controller 400.

The first clock domain 100-1B may include a first clock mesh driver block (e.g., a first clock tree circuit) 110-1, a first clock mesh network (e.g., a first mesh wiring) 130-1, a first local clock gating block 150-1, and a first load block 170-1. The first clock mesh driver block 110-1 may receive a clock CLK output from the first clock gating circuit 300-1 and include a plurality of hierarchy structure buffers (or drivers) for driving the first clock mesh network 130-1 using the clock CLK.

In one embodiment, an operation and a structure of the SoC 80C in FIG. 4 are substantially the same as those of the SoC 80B in FIG. 4 except for connection structures of the first and second switch circuits 200-1 and 200-2.

In example embodiments, the first switch circuit 200-1 may connect a node N14 of the first clock domain 100-1B to a node N24 of the second clock domain 100-2B in response to a first switch signal SS1 output from the switch controller 400. For example, the first clock mesh driver block 110-1 of the first clock domain 100-1B and the second clock mesh driver block 110-2 of the second clock domain 100-2B may be connected with each other by the first switch circuit 200-1.

When the first switch circuit 200-1 is switched on, a clock signal received at the first load block 170-1 of the first clock domain 100-1B and a clock signal received at a second load block 170-2 of the second clock domain 100-2B may be synchronized with each other.

In example embodiments, the second switch circuit 200-2 may connect a node N24 of the second clock domain 100-2B with a node N34 of the third clock domain 100-3B in response to a second switch signal SS2 output from the switch controller 400. When the second switch circuit 200-2 is switched on, a clock signal received at the second load block 170-2 of the second clock domain 100-2B and a clock signal received at a third load block 170-3 of the third clock domain 100-3B may be synchronized with each other.

Each clock gating circuit 300-1, 300-2, 300-3, and 300-4 may supply or block a clock CLK to or from each clock domain 100-1B, 100-2B, and 100-3B in response to each enable signal EN1, EN2, EN3, and EN4. As described referring to Table 1, the switch controller 400 may generate each switch signal SS1 and SS2 corresponding to a state mode.

Except each node N14, N24, and N34 connected by each switch 200-1 and 200-2, a structure and an operation of each clock domain 100-1B, 100-2B, and 100-3B illustrated in FIG. 4 are substantially the same.

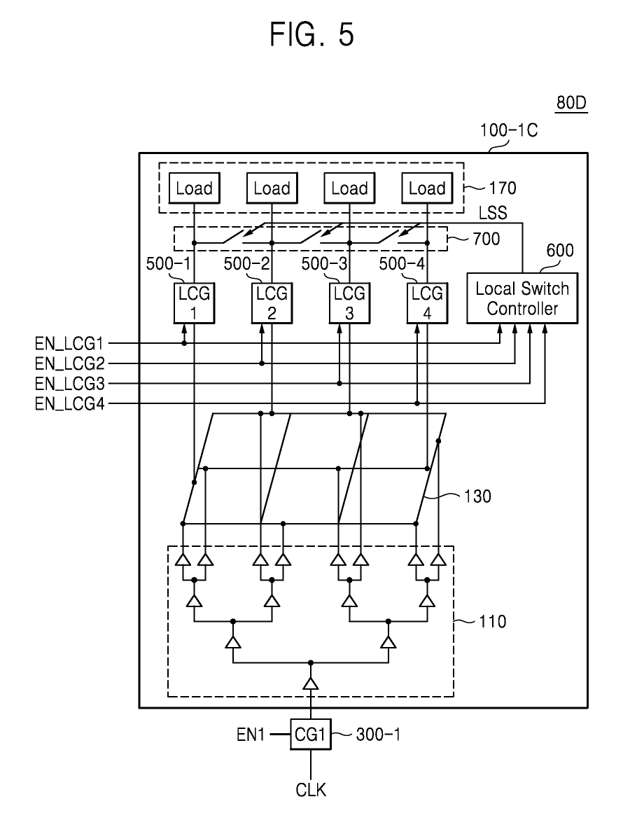

FIG. 5 is a block diagram which represents still another exemplary embodiment of the SoC including a clock mesh circuit having a local clock gating circuit. An SoC 80D of FIG. 5 includes a first clock domain 100-1C and a first clock gating circuit 300-1. The first clock domain 100-1C of FIG. 5 may be understood as an exemplary embodiment of the first clock domain 100-1 of FIG. 2.

The first clock domain 100-1C includes a clock driver block 110, a clock mesh network 130, a plurality of local clock gating circuits 500-1, 500-2, 500-3, and 500-4, a local switch controller 600, a local switch circuit 700, and a load block 170.

In example embodiments, the first local clock gating circuit 500-1 may transmit or block a clock CLK to or from a corresponding load of the load block 170 in response to a first local enable signal EN LCG1 output from the CPU 20 or the CMU 30. The second local clock gating circuit 500-2 may transmit or block a clock CLK to or from a corresponding load of the load block 170 in response to a second local enable signal EN LCG2 output from the CPU 20 or the CMU 30. The third local clock gating circuit 500-3 may transmit or block a clock CLK to or from a corresponding load of the load block 170 in response to a third local enable signal EN LCG3 output from the CPU 20 or the CMU 30. The fourth local clock gating circuit 500-4 may transmit or block a clock CLK to or from a corresponding load of the load block 170 in response to a fourth local enable signal EN LCG4 output from the CPU 20 or the CMU 30.

The local switch controller 600 may generate a local switch signal LSS in response to a plurality of local enable signals EN LCG1, EN LCG2, EN LCG3, and EN LCG4. The local switch circuit 700 may connect output terminals of a plurality of local clock gating circuits 500-1, 500-2, 500-3, and 500-4 each other in response to the local switch signal LSS output from the local switch controller 600.

When connecting the output terminals of the plurality of local clock gating circuits 500-1, 500-2, 500-3, and 500-4, a clock CLK supplied to each load of the load block 170 may be synchronized with the others. Accordingly, the SoC 80D of FIG. 5, compared to each SoC 80B and 80C, can accurately control a clock CLK supplied to the first clock domain 100-1C. For example, the local switch circuit 700 of the SoC 80D may be embodied smaller than each switch circuit 200-1 and 200-2 of each SoC 80B and 80C in size.

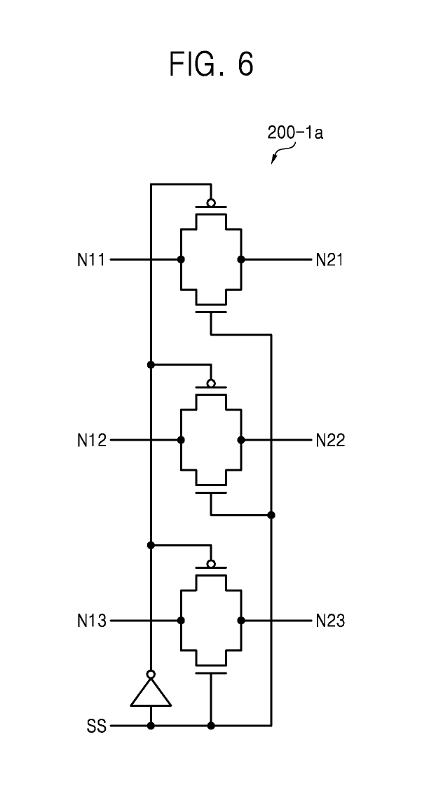

FIG. 6 is a circuit diagram which represents an exemplary embodiment of a switch circuit illustrated in FIG. 3. A first switch circuit 200-1a according to an exemplary embodiment of the first switch circuit 200-1 of FIG. 3 includes a plurality of transmission gates and an inverter. Each of the plurality of transmission gates is connected between each node (e.g., N11, N12, and N13) of a first clock domain (e.g., 100-1A) and each node (e.g., N21, N22, and N23) of the second clock domain (e.g., 100-2A) in response to a switch signal SS. In one embodiment, the first switch circuit 200-1a may include one inverter and one transmission gate having one end connected to the nodes N11, N12, and N13 and one end connected to the nodes N21, N22, and N23.

A switch signal inverted by the inverter is supplied to a gate of each PMOS transistor of each transmission gate, and the switch signal SS is supplied to a gate of each NMOS transistor of the each transmission gate. A structure of the first switch circuit 200-1a is substantially the same as a structure of the second switch circuit 200-2 of FIG. 3.

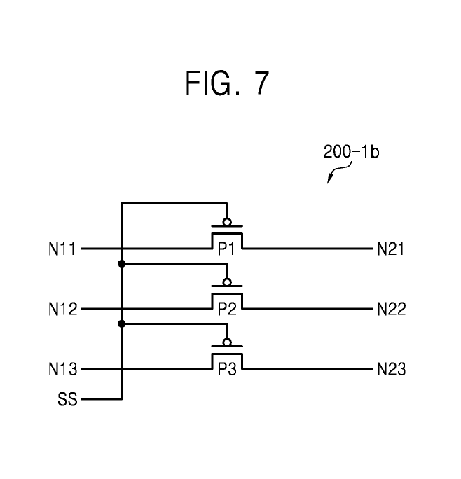

FIG. 7 is a circuit diagram which represents another exemplary embodiment of the switch circuit illustrated in FIG. 3.

A first switch circuit 200-1b according to another exemplary embodiment of the first switch circuit 200-1 of FIG. 3 includes a plurality of PMOS transistors P1, P2, and P3. Each PMOS transistor P1, P2, and P3 connects each node N11, N12, and N13 of the first clock domain 100-1A to each node N21, N22, and N23 of the second clock domain 100-2A in response to a switch signal SS. A structure of the first switch circuit 200-1b is the same as the structure of the second switch circuit 200-2 of FIG. 3. In one embodiment, the first switch circuit 200-1b may include one PMOS transistor having one end connected to the nodes N11, N12, and N13 and one end connected to the nodes N21, N22, and N23.

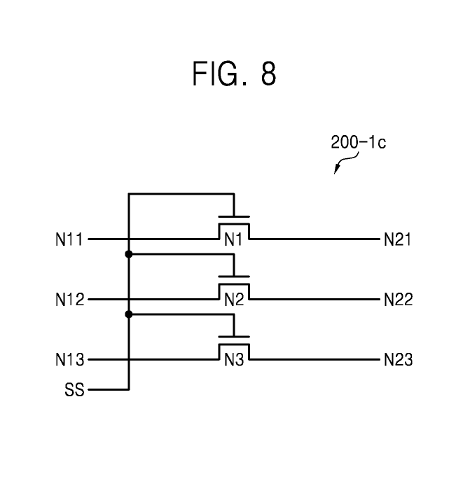

FIG. 8 is a circuit diagram which represents still another exemplary embodiment of the switch circuit illustrated in FIG. 3. A switch circuit 200-1c according to still another exemplary embodiment of the first switch circuit 200-1 of FIG. 3 includes a plurality of NMOS transistors N1, N2, and N3. Each NMOS transistor N1, N2, and N3 connects each node N11, N12, and N13 of the first clock domain 100-1 with each node N21, N22, and N23 of the second clock domain 100-2 in response to a switch signal SS. In one embodiment, the first switch circuit 200-1c may include one NMOS transistor having one end connected to the nodes N11, N12, and N13 and one end connected to the nodes N21, N22, and N23.

A structure of the first switch circuit 200-1c is the same as the structure of the second switch circuit 200-2 of FIG. 3. Each switch circuit 200, 200-1, and 200-2 may be one of switch circuit 200-1a, 200-1b, or 200-1c.

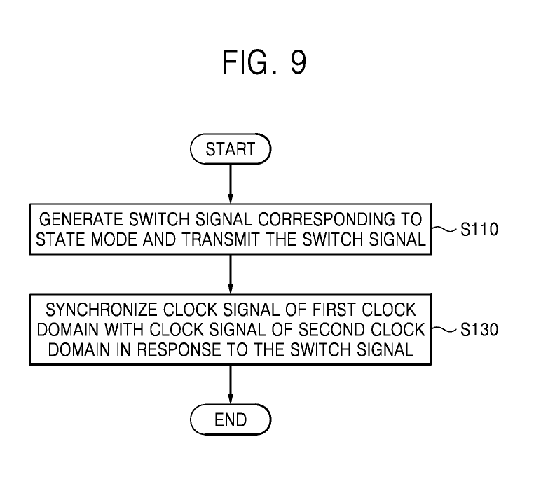

FIG. 9 is a flowchart which represents a method of operating the system on chip including a clock mesh circuit according to an exemplary embodiment of the present inventive concepts. Referring to FIGS. 1 to 9, the switch controller 400 may generate each switch signal SS or SS1 corresponding to each state mode, and transmit each switch signal SS or SS1 to each switch circuit 200 or 200-1 (step S110).

Each switch circuit 200 or 200-1 may connect each first clock domain 100-1 or 100-1A to each second clock domain 100-2 or 100-2A in response to each switch signal SS or SS1 (step S130). Accordingly, a clock signal received at a load circuit of the first clock domain 100-1 or 100-1A and a clock signal received at a load circuit of the second clock domain 100-2 or 100-2A are synchronized with each other.

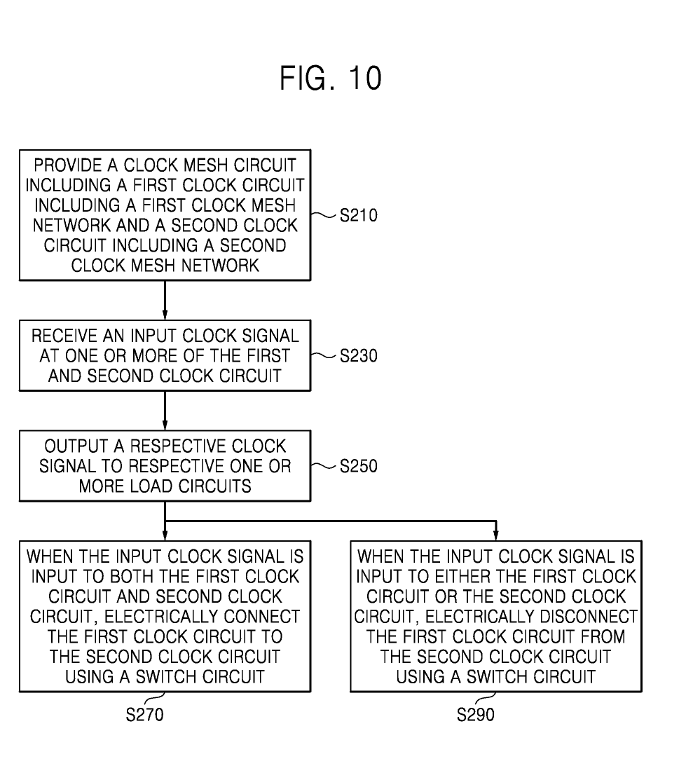

FIG. 10 is a flowchart which represents a method of providing a clock signal to one or more load circuits using a clock mesh circuit according to an exemplary embodiment of the present inventive concepts. Referring to FIGS. 1 to 8, and 10, a clock mesh circuit is provided (step S210). For example, the clock mesh circuit may include a first clock circuit and a second clock circuit. The first clock circuit may include a first clock mesh network and a first clock mesh drive block. The second clock circuit may include a second clock mesh network and a second clock mesh drive block.

In step S230, one or more of the first and second clock circuits receive an input clock signal, and then the first and second clock circuits output a respective output clock signal to respective one or more load circuits (step S250). In one embodiment, when the input clock signal is input to both the first clock circuit and the second clock circuit, a switch circuit electrically connects the first clock circuit to the second clock circuit (step S270). In another embodiment, when the input clock signal is input to either the first clock circuit or the second clock circuit but not both, a switch circuit electrically disconnects the first clock circuit to the second clock circuit (step S290).

The clock mesh circuit according to an exemplary embodiment of the present inventive concepts may reduce a change (or variation) in a delay of a clock by synchronizing the clock with the other clocks using a switch circuit embodied between multiple clock meshes.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A clock mesh circuit comprising:
a first clock circuit including a first clock mesh network, and configured to transmit a received clock signal to a first load circuit;
a second clock circuit including a second clock mesh network separate from the first clock mesh network, and configured to transmit the clock signal to a second load circuit; and
a switch circuit connecting the first clock mesh network to the second clock mesh network,
wherein the clock mesh circuit is configured such that the clock signal is transmitted to the first and second load circuits when the switch circuit is turned-on, and the clock signal is transmitted to either the first load circuit or the second load circuit when the switch circuit is turned-off.

2. The clock mesh circuit of claim 1, wherein the switch circuit connects the first clock mesh network to the second clock mesh network in response to a switch signal output from a switch controller.

3. The clock mesh circuit of claim 1, wherein a clock signal received at the first load circuit and a clock signal received at the second load circuit are synchronized with each other when the switch circuit is turned-on.

4. The clock mesh circuit of claim 1, wherein the first and second clock circuits further include a first clock mesh driver and a second clock mesh driver, respectively, and wherein the switch circuit electrically connects the first clock mesh driver to the second clock mesh driver in response to a switch signal output from a switch controller.

5. The clock mesh circuit of claim 4, wherein the first clock mesh driver includes a first hierarchy structure of first drivers configured to drive the first clock mesh network, and
the second clock mesh driver includes a second hierarchy structure of second drivers configured to drive the second clock mesh network.

6. The clock mesh circuit of claim 1, wherein the first load circuit includes a plurality of load circuits, and
wherein the first clock circuit further includes:
a plurality of local clock gating circuits configured to transmit or block a clock signal output from the first clock mesh network to or from a corresponding load circuit of the load circuits in response to a respective enable signal; and
a local switch circuit configured to connect output terminals of the plurality of local clock gating circuits to each other in response to a local switch signal.

7. The clock mesh circuit of claim 1, wherein the switch circuit includes at least one of a transmission gate, an NMOS transistor, and a PMOS transistor.

8. The clock mesh circuit of claim 1, wherein the clock mesh circuit is included in a system on chip (SoC).

9. A method of providing a clock signal to one or more load circuits using a clock mesh circuit:
wherein the clock mesh circuit comprises:
a first clock circuit including a first clock mesh network configured to receive an input clock signal and to output a first output clock signal to a first load circuit;
a second clock circuit including a second clock mesh network configured to receive the input clock signal and to output a second output clock signal to a second load circuit; and
a switch circuit configured to electrically connect and electrically disconnect the first clock circuit to and from the second clock circuit;
the method comprising:
receiving the input clock signal at one or more of the first and second clock circuits;
outputting a respective output clock signal to respective one or more load circuits based on the received input clock signal;
when the input clock signal is input to both the first clock circuit and the second clock circuit, electrically connecting the first clock circuit to the second clock circuit using the switch circuit; and
when the input clock signal is input to either the first clock circuit or the second clock circuit but not both, electrically disconnecting the first clock circuit from the second clock circuit using the switch circuit.

10. The method of claim 9, wherein receiving the input clock signal includes turning on and off first and second clock gating circuits in response to first and second enable signals, respectively, in order to allow or prevent a clock signal from being input to the first and second clock circuits.

11. The method of claim 9, wherein the first output clock signal is synchronized with the second output clock signal when the switch circuit is turned-on.

12. The method of claim 9, wherein each of the first and second load circuits includes at least one of a flip-flop circuit, a central processing unit, a memory, a memory controller, and a display controller.

13. The method of claim 9, wherein the input clock signal is received from a DLL circuit or a PLL circuit.

14. A semiconductor device comprising:
a first clock circuit including a first clock distribution circuit including a first clock tree circuit and a first mesh wiring that contacts output terminals of the first clock tree circuit, and a first clock gating circuit configured to transmit a clock signal to the first clock tree circuit in response to a first enable signal;
a second clock circuit including a second clock distribution circuit including a second clock tree circuit and a second mesh wiring that contacts output terminals of the second clock tree circuit, and a second clock gating circuit configured to transmit the clock signal to the second clock tree circuit in response to a second enable signal; and
a switch circuit configured to electrically connect and disconnect the first clock distribution circuit to/from the second clock distribution circuit in response to a switch signal.

15. The semiconductor device of claim 14, wherein the first clock circuit is configured to transmit a first output clock signal based on the clock signal to a first load circuit and the second clock circuit is configured to transmit a second output clock signal based on the clock signal to a second load circuit, and
wherein when the switch circuit is turned-on the clock signal is transmitted to both the first and second clock circuits, and when the switch circuit is turned-off the clock signal is transmitted to either the first or second clock circuit but not both.

16. The semiconductor device of claim 15, wherein the switch circuit connects the first mesh wiring to the second mesh wiring.

17. The semiconductor device of claim 15, wherein the switch circuit connects the first clock tree circuit to the second clock tree circuit.

18. The semiconductor device of claim 15, wherein the switch circuit includes at least one of a transmission gate, an NMOS transistor, and a PMOS transistor.

19. The semiconductor device of claim 15, further comprising:
a first local clock driver configured to transmit the clock signal from the first clock tree circuit as the first output clock signal to the first load circuit; and
a second local clock driver configured to transmit the clock signal from the second clock tree circuit as the second output clock signal to the second load circuit.

20. The semiconductor device of claim 19, wherein each of the first and second load circuits includes at least one of a flip-flop circuit, a central processing unit, a memory, a memory controller, and a display controller.
